(19) United States
(12) Patent Application Publication
(10) Pub. No.: US 2026/0144139 A1
(43) Pub. Date: May 21, 2026

(54) SEMICONDUCTOR DEVICE

(71) Applicant: FUJI ELECTRIC CO., LTD., Kawasaki-shi (JP)

(72) Inventor: Miku HIROWATARI, Matsumoto-city (JP)

(73) Assignee: FUJI ELECTRIC CO., LTD., Kawasaki-shi (JP)

(21) Appl. No.: 19/313,494

(22) Filed: Aug. 28, 2025

(30) Foreign Application Priority Data
Nov. 15, 2024 (JP) 2024-199934

(51) Int. Cl. H01L 23/24; H01L 23/055; H01L 23/29

(52) U.S. Cl. CPC H10W 76/47; H10W 74/476; H10W 76/153

(57) ABSTRACT

To prevent leakage of an oily component seeping from an insulating sealing resin, a semiconductor device includes a case member 2 having a recess 3, a semiconductor chip 20A provided in the recess 3 of the case member 2, a sealing resin 30 containing an oily component and provided in the recess 3 of the case member 2 to cover the semiconductor chip 20A, a lid member 40 fixed to the case member 2 to close the opening of the recess 3 of the case member 2, and an oily component absorber 50 placed between the sealing resin 30 and the lid member 40 to absorb the oily component seeping from the sealing resin 30.

### CROSS REFERENCE TO RELATED APPLICATIONS AND INCORPORATION BY REFERENCE

This application claims benefit of priority under 35 U.S.C. § 119 based on Japanese Patent Application No. 2024-199934 filed on Nov. 15, 2024, the entire contents of which are incorporated by reference herein.

### TECHNICAL FIELD

The technology (the technology of the present disclosure) relates to a semiconductor device and specifically relates to a technology effectively applicable to a semiconductor device including a sealing resin provided in a recess of a case member to cover a semiconductor chip.

### BACKGROUND ART

A semiconductor device includes a case member having a recess, a sealing resin provided in the recess of the case member to cover a semiconductor chip, and a lid member fixed to the case member to close the opening of the recess of the case member. As the technology relating to this kind of semiconductor device, Patent Documents 1 to 4 (which correspond to “JP 2023-042658 A”, “JP 2003-297979 A”, “JP 2017-059715 A”, and “JP 2011-243798 A”, respectively) disclose a technology of preventing external leakage of a sealing resin and a technology of preventing external leakage of an oil and fat component seeping from a sealing resin.

### SUMMARY OF INVENTION

### Technical Problem

The technology is intended to provide a novel technology capable of suppressing external leakage of an oil component seeping from a sealing resin.

### Solution to Problem

(1) A semiconductor device according to an aspect of the technology includes
a case member having a recess,
a semiconductor chip provided in the recess of the case member,
a sealing resin containing an oily component and provided in the recess of the case member to cover the semiconductor chip,
a lid member fixed to the case member to close the opening of the recess of the case member, and
an oily component absorber placed between the sealing resin and the lid member to absorb the oily component seeping from the sealing resin.

(2) In a semiconductor device according to an aspect of the technology,
the oily component absorber is a plate-shaped inner lid member having a recess on a surface adjacent to the sealing resin, and the recess is recessed in a direction away from the sealing resin.

(3) In a semiconductor device according to an aspect of the technology,
the oily component absorber is a plate-shaped porous insulating member having internal pores.

### ADVANTAGEOUS EFFECTS OF INVENTION

According to an aspect of the present technology, external leakage of an oil component seeping from a sealing resin can be suppressed.

### BRIEF DESCRIPTION OF DRAWINGS

FIG. 1 is a plan view schematically illustrating the external structure of a semiconductor device according to a first embodiment of the present technology.

FIG. 2 is a longitudinal sectional view schematically illustrating a cross-sectional structure taken along line II-II in FIG. 1.

FIG. 3 is a longitudinal sectional view of an enlarged main portion in FIG. 2.

FIG. 4 is a longitudinal sectional view of a main portion schematically illustrating an example state in which a thermally expanded sealing resin is in contact with an inner lid member in the first embodiment of the present technology.

FIG. 5 is a plan view illustrating a flat pattern of recesses provided on a surface of the inner lid member adjacent to the sealing resin.

FIG. 6 is a plan view illustrating a flat pattern of recesses of an inner lid member in an alternative embodiment 1-1 according to the first embodiment of the present technology.

FIG. 7 is a plan view illustrating a flat pattern of recesses of an inner lid member in an alternative embodiment 1-2 according to the first embodiment of the present technology.

FIG. 8 is a plan view illustrating a flat pattern of recesses of an inner lid member in an alternative embodiment 1-3 according to the first embodiment of the present technology.

FIG. 9 is a plan view illustrating a flat pattern of a recess of an inner lid member in an alternative embodiment 1-4 according to the first embodiment of the present technology.

FIG. 10 is a longitudinal sectional view schematically illustrating the inner structure of a semiconductor device according to a second embodiment of the present technology.

FIG. 11 is a longitudinal sectional view of an enlarged main portion in FIG. 10.

FIG. 12 is a longitudinal sectional view of a main portion schematically illustrating an example state in which a thermally expanded sealing resin is in contact with a porous insulating member in the second embodiment of the present technology.

FIG. 13 is a plan view schematically illustrating the external structure of a semiconductor device according to a third embodiment of the present technology.

FIG. 14 is a plan view schematically illustrating the external structure of a semiconductor device according to a fourth embodiment of the present technology.

### DESCRIPTION OF EMBODIMENTS

Embodiments of the present technology will now be described in detail with reference to drawings.

In the description of drawings referred to in the following description, identical or similar components are indicated by an identical or similar sign. It should be noted that the drawings are schematic, and the relationship between thickness and plan dimension, the ratio of thicknesses of layers, or the like may differ from the actual ones. Therefore, specific thicknesses and dimensions should be determined by referring to the following description.

Needless to say, the dimensional relationships or ratios may differ between drawings. The effects described in the present description are merely illustrative examples and are not limited, and other effects may be included.

The embodiments described below are merely illustrative examples of devices or methods for embodying the technical idea of the present technology and do not limit the structure to the following. In other words, the technical idea of the present technology may be modified in various ways within the technical scope described in claims.

In the following description, the definitions of directions such as “up”, “down”, “vertical”, “left”, “right”, and “horizontal” directions are merely for convenience of explanation and do not limit the technical idea of the present technology. For example, when an object is rotated by 90° and observed, the up and down directions are converted to left and right directions, and when an object is rotated by 180° and observed, the up and down directions are inverted, needless to say.

In the following description, a “top surface” and a “bottom surface” may be read as a “front surface” and a “back surface”, respectively. A “first principal surface” and a “second principal surface” of a member are the principal surfaces located opposite to each other, and when the “first principal surface” is the top surface, the “second principal surface” is the bottom surface. A “first principal surface” and a “second principal surface” may be read as “one principal surface” and “the other principal surface”.

In the following embodiments, of three directions orthogonal to each other in a space, a first direction and a second direction orthogonal to each other in the same plane is defined as X direction and Y direction, respectively, and a third direction orthogonal to the first direction and the second direction is defined as Z direction. In the following embodiments, the thickness direction of a case member described later is defined as Z direction in the description.

In the present description, when the transistor included in a transistor chip is a field-effect transistor (FET), a static induction transistor (SIT), or the like, the first main electrode means one electrode of a source electrode and a drain electrode, the second main electrode means the other electrode, and the control electrode means a gate electrode. When the transistor included in a transistor chip is a bipolar junction transistor (BJT) or the like, the first main electrode means one electrode of an emitter electrode and a collector electrode, the second main electrode means the other electrode, and the control electrode means a base electrode. When the transistor included in a transistor chip is an insulated gate bipolar transistor (IGBT) or the like, the first main electrode means one electrode of an emitter electrode and a collector electrode, the second main electrode means the other electrode, and the control electrode means a gate electrode. In the following embodiments, a MISFET, an insulated gate field-effect transistor, is focused as the transistor included in a semiconductor chip and will be described. Accordingly, the first main electrode is a source electrode, the second main electrode is a drain electrode, and the control electrode is a gate electrode in the description.

In the following embodiments, plan view is a view of a semiconductor device viewed in the Z direction. Sectional view is a view of a cross section along the Z direction, viewed in the direction (Y direction) orthogonal to the cross section.

### First Embodiment

In the first embodiment, an example in which the present technology is applied to a semiconductor device as a power device to be incorporated into a power conversion system that converts electricity from direct current to alternating current will be described.

In the first embodiment, a device including, as an oil component absorber of the present technology, a plate-shaped inner lid member having recesses on a surface adjacent to a sealing resin will be described.

### <<Entire Structure of Semiconductor Device>>

First, the entire structure of a semiconductor device will be described.

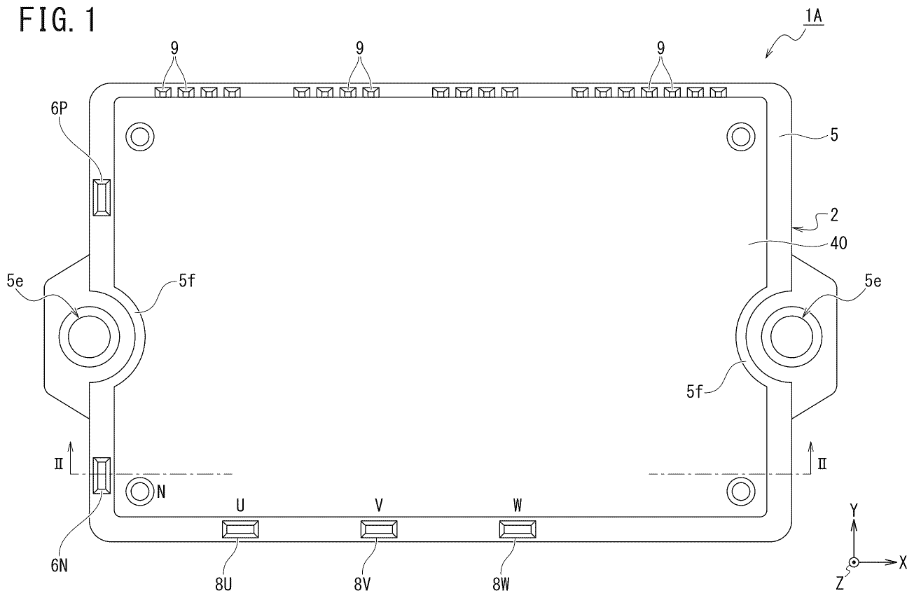

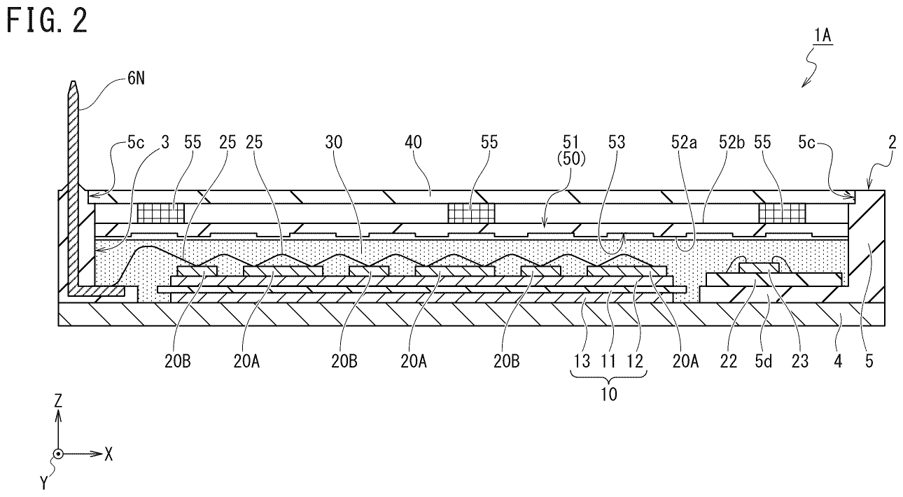

As illustrated in FIG. 1 and FIG. 2, a semiconductor device 1A according to the first embodiment of the present technology includes a case member 2 having a recess 3, semiconductor chips 20 and a bonding wire 25 provided in the recess 3 of the case member 2, and a sealing resin 30 containing an oily component and provided in the recess 3 of the case member 2 to cover the semiconductor chips 20.

The semiconductor device 1A according to the first embodiment of the present technology further includes a lid member 40 fixed to the case member 2 to close the opening of the recess 3 of the case member 2 and an inner lid member 51 as an oily component absorber 50 placed between the sealing resin 30 and the lid member 40 to absorb an oily component seeping from the sealing resin 30.

The semiconductor device 1A according to the first embodiment of the present technology further includes an insulating circuit board 10 provided in the recess 3 of the case member 2, and on the insulating circuit board, the semiconductor chips 20 and the bonding wire 25 are installed.

The semiconductor device 1A according to the first embodiment of the present technology includes, as external connection terminals formed integrally with a frame 5 of the case member 2, a positive electrode terminal 6P, a negative electrode terminal 6N, three output terminals 8U, 8V, 8W, and a plurality of control terminals (auxiliary terminals) 9. These external connection terminals are electrically connected to the semiconductor chips described later.

### <Case Member>

As illustrated in FIG. 2, the case member 2 includes the recess 3 and further includes a radiator plate 4 and a frame 5 that is fixed to the radiator plate 4 and surrounds the periphery of the semiconductor chips 20. The recess 3 of the case member 2 is defined by the radiator plate 4 and the frame 5.

As illustrated in FIG. 1, the frame 5 is rectangular in plan view and has, for example, a rectangular shape. Not specifically illustrated, the outer peripheral edge of the frame 5 in plan view has two long sides positioned opposite to each other in the short direction as the Y direction and extending in the longitudinal direction as the X direction orthogonal to the Y direction and has two short sides positioned opposite to each other in the length direction (X direction) and extending in the Y direction. With reference to FIG. 2, the frame 5 has a thickness in the Z direction orthogonal to the X direction and the Y direction and has a principal surface and a back surface positioned opposite to each other.

As illustrated in FIG. 2, the radiator plate 4 is provided on the back surface of the frame 5. Not specifically illustrated, the radiator plate 4 is rectangular in plan view and has, for example, a rectangular shape similar to the frame 5 in plan view. The outer dimensions of the radiator plate 4 in plan view are substantially the same as the outer dimensions of the frame 5 in plan view.

The outer peripheral edge of the radiator plate 4 in plan view has two long sides and two short sides as with the frame 5. With reference to FIG. 2, the radiator plate has a thickness in the Z direction orthogonal to the X direction and the Y direction and has a principal surface and a back surface positioned opposite to each other.

The radiator plate 4 mainly includes a metal or a composite material having excellent thermal conductivity. Examples of the metal include copper, aluminum, and an alloy containing at least one of them. The radiator plate may include a composite material containing a metal such as aluminum and magnesium and silicon carbide. The radiator plate 4 preferably has a thickness of 1.0 mm or more and 20.0 mm or less. To improve the corrosion resistance, the surface of the radiator plate 4 may be plated. Examples of the plating material used for the radiator plate include nickel, a nickel-phosphorus alloy, and a nickel-boron alloy.

The frame 5 includes, for example, a thermoplastic resin. Examples of the thermoplastic resin include a polyphenylene sulfide resin, a polybutylene terephthalate resin, a polybutylene succinate resin, a polyamide resin, and an acrylonitrile butadiene styrene resin. Such a resin may contain a filler. Examples of the filler include glass, silicon oxide, aluminum oxide, silicon nitride, and boron nitride. Such a resin is filled in a predetermined mold and is solidified, and then the mold is removed. Accordingly, the frame 5 is formed.

As illustrated in FIG. 2, the back surface of the frame 5 is adhesively fixed to the principal surface of the radiator plate 4 through an adhesive (not illustrated). By adhesively fixing the frame 5 to the radiator plate 4, a case member 2 having a recess 3 is formed. The adhesive mainly includes an organic adhesive. The organic adhesive has a heat-resistant temperature of about 100° C. to 200° C. The organic adhesive is specifically an epoxy adhesive, a silicon adhesive, or an acrylic adhesive. The adhesive may be a paste adhesive or a sheet adhesive.

As illustrated in FIG. 2, on the principal surface of the frame 5, a step 5c lower than the principal surface is provided. Not specifically illustrated, the step 5c is annularly formed along the outer peripheral edge of the frame 5 in plan view and is linked to the recess 3 on the opening side of the recess 3. Into the step 5c, the lid member 40 is fitted.

<insulating Circuit Board>

As illustrated in FIG. 2, the insulating circuit board 10 includes an insulating plate 11, a circuit pattern 12, and a metal plate 13. Each of the insulating plate 11 and the metal plate 13 is rectangular in plan view and has, for example, a rectangular shape. The planar dimensions of the metal plate 13 are smaller than the planar dimensions of the insulating plate 11, and the outer peripheral edge (outline) of the metal plate 13 is located inside the outer peripheral edge (outline) of the insulating plate 11. Each of the insulating plate 11, the circuit pattern 12, and the metal plate 13 has a principal surface and a back surface positioned opposite to each other in the thickness direction (Z direction).

The insulating plate 11 includes a material having insulating properties and excellent thermal conductivity. Such an insulating plate 11 includes, for example, a ceramic or an insulating resin. Examples of the ceramic include aluminum oxide, aluminum nitride, and silicon nitride. Examples of the insulating resin include a paper phenol substrate, a paper epoxy substrate, a glass composite substrate, and a glass epoxy substrate. The insulating plate 11 has a thickness of, for example, 0.2 mm or more and 2.5 mm or less.

As illustrated in FIG. 2, the circuit pattern 12 is provided on the principal surface of the insulating plate 11, and the back surface of the circuit pattern 12 is joined to the principal surface of the insulating plate 11. The circuit pattern 12 includes a metal having excellent electric conductivity. Such a metal is copper, aluminum, or an alloy mainly containing at least one of them. The circuit pattern 12 has a thickness of, for example, 0.1 mm or more and 2.0 mm or less. To improve the corrosion resistance, the surface of the circuit pattern 12 may be plated. Examples of the plating material used for the circuit pattern include nickel, a nickel-phosphorus alloy, and a nickel-boron alloy.

The circuit pattern 12 is formed on the principal surface of the insulating plate 11 as follows: On the principal surface of the insulating plate 11, a metal plate is formed; then the metal plate is subjected to processing such as etching; and a circuit pattern 12 having a predetermined shape is prepared. Alternatively, a circuit pattern 12 previously cut out from a metal plate may be pressure-bonded to the principal surface of the insulating plate 11.

The circuit pattern 12 illustrated in FIG. 2 is merely an example, and the number, the shape, and the position of circuit patterns 12 may be appropriately selected.

As illustrated in FIG. 2, the metal plate 13 is provided on the back surface of the insulating plate 11, and the back surface of the metal plate 13 is joined to the back surface of the insulating plate 11. The metal plate 13 is superimposed on the insulating plate 11 in plan view and is formed over the whole region of the insulating plate 11 except the peripheral edge portion.

The metal plate 13 mainly includes a metal having excellent thermal conductivity. Examples of the metal include copper, aluminum, and an alloy containing at least one of them. The metal plate 13 has a thickness of, for example, 0.1 mm or more and 2.5 mm or less. To improve the corrosion resistance, the surface of the metal plate 13 may be plated. Examples of the plating material used for the metal plate include nickel, a nickel-phosphorus alloy, and a nickel-boron alloy.

The metal plate 13 is formed on the back surface of the insulating plate 11 as follows: On the back surface of the insulating plate 11, a metal plate is formed; then the metal plate is subjected to processing such as etching; and a metal plate 13 is prepared. Alternatively, a metal plate 13 previously cut out from a metal plate may be pressure-bonded to the back surface of the insulating plate 11. On the metal plate 13 provided on the back surface of the insulating plate 11 as above, the corners may be chamfered into round faces or bevel faces.

As the insulating circuit board 10 having such a structure, a DCB (direct copper bonding) substrate, an AMB (active metal brazed) substrate, or a resin insulating substrate may be used. Heat generated in the semiconductor chips 20 conducts through the insulating plate 11, the circuit pattern 12, and the metal plate 13 to the radiator plate 4 and dissipates to the outside.

The number of insulating circuit boards 10 is not limited to one as illustrated in FIG. 2, but a plurality of insulating circuit boards may be provided.

### <Semiconductor Chip>

As illustrated in FIG. 2, on the circuit pattern 12 of the insulating circuit board 10, semiconductor chips 20A and 20B are mounted. A plurality of semiconductor chips 20A and a plurality of semiconductor chips 20B are mounted. In FIG. 2, three semiconductor chips 20A and two semiconductor chips 20B are illustrated, but the number of semiconductor chips 20A and the number of semiconductor chips 20B are not limited to the numbers illustrated in FIG. 2.

The semiconductor chip 20A illustrated in FIG. 2 includes a switching element as the power device element including a semiconductor such as silicon, silicon carbide, or gallium nitride. The semiconductor chip 20B illustrated in FIG. 2 includes a diode element as the power device element including a semiconductor such as silicon, silicon carbide, or gallium nitride.

The switching element is, for example, an insulated gate bipolar transistor (IGBT) or a metal insulator semiconductor field effect transistor (MISFET). Such a semiconductor chip 20A has, for example, a principal surface and a back surface positioned opposite to each other in the thickness direction (Z direction) of the semiconductor chip 20A, a control electrode and a first main electrode provided on the principal surface, and a second main electrode provided on the back surface. When the switching element is an IGBT, for example, the first main electrode functions as the emitter electrode, the second main electrode functions as the collector electrode, and the control electrode functions as the gate electrode. When the switching element is a MISFET, for example, the first main electrode functions as the source electrode, the second main electrode functions as the drain region, and the control electrode functions as the gate electrode.

The diode element is, for example, a FWD (free wheeling diode) such as a schottky barrier diode (SBD) and a PiN (P-intrinsic-N) diode. Such a semiconductor chip 20B has a principal surface and a back surface positioned opposite to each other in the thickness direction (Z direction) of the semiconductor chip 20B, a cathode electrode as the first main electrode provided on the principal surface, and an anode electrode as the second main electrode provided on the back surface.

The back surfaces of the semiconductor chips 20A and 20B are electrically and mechanically joined through a joining material (not illustrated) to a predetermined circuit pattern 12. The joining material is solder or a metal sintered body. As the solder, lead-free solder is used. The lead-free solder mainly includes, for example, an alloy containing at least two of tin, silver, copper, zinc, antimony, indium, and bismuth. The solder may contain an additive. Examples of the additive include nickel, germanium, cobalt, and silicon. By adding the additive to the solder, the surface wettability, gloss, and binding strength are improved, and the reliability is to be improved. Examples of the metal used in the metal sintered body include silver and a silver alloy.

In place of the semiconductor chips 20A and 20B, a semiconductor chip including an RC (reverse-conducting)-IGBT having both functions of IGBT and FWD may be used.

<external Connection Terminal>

As illustrated in FIG. 1, the positive electrode terminal 6P and the negative electrode terminal 6N as external connection terminals are provided on one short side (the left side in FIG. 1) of two short sides included in the outer peripheral edge of the frame 5 in plan view and are arranged at a certain interval in the extending direction of the one short side.

As illustrated in FIG. 1, three output terminals 8U, 8V, 8W as external connection terminals are provided on one long side (the lower side in FIG. 1) of two long sides included in the outer peripheral edge of the frame 5 in plan view and are arranged at certain intervals in the extending direction of the one long side.

As illustrated in FIG. 1, a plurality of control terminals 9 as external connection terminals are provided on the other long side (the upper side in FIG. 1) of two long sides included in the outer peripheral edge of the frame 5 in plan view and are arranged at certain intervals in the extending direction of the other long side.

As illustrated in FIG. 2, the negative electrode terminal 6N extends through the frame 5 in the thickness direction (Z direction) of the frame 5, and one end protrudes outward from the principal surface of the frame 5. Not illustrated, the positive electrode terminal 6P, the three output terminals 8U, 8V, 8W, and the plurality of control terminals 9 each extend through the frame 5 in the thickness direction (Z direction) of the frame 5, and one ends protrude outward from the principal surface of the frame 5, as with the negative electrode terminal 6N.

As illustrated in FIG. 2, the other end of the negative electrode terminal 6N is bent inward in the frame 5 and is exposed from the frame 5 as a connection portion. Not illustrated, the other ends of the positive electrode terminal 6P, the three output terminal 8U, 8V, 8W, and the plurality of control terminals 9 are also each bent inward in the frame and are exposed from the frame 5 as connection portions 5 as with the other end of the negative electrode terminal 6N.

### <Electrical Connection Between External Connection Terminal and Semiconductor Chip>

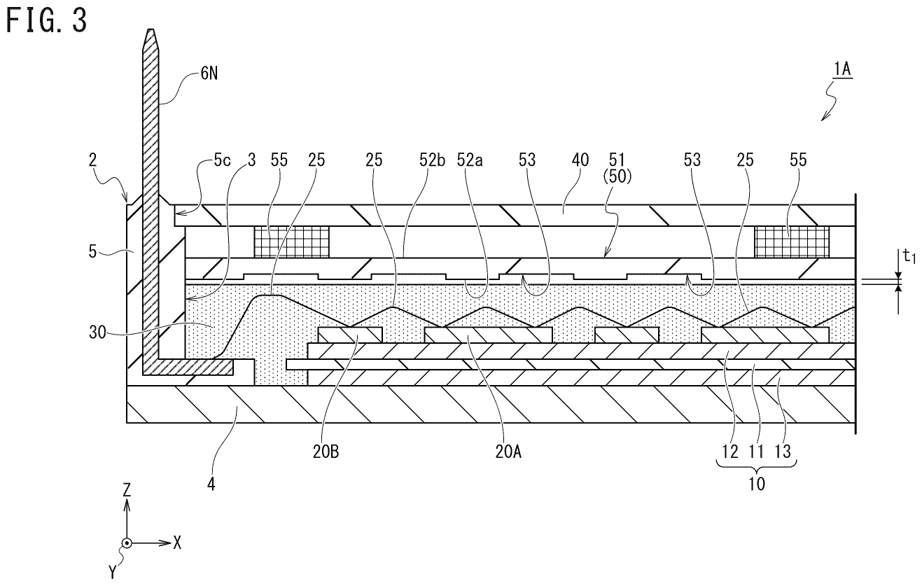

Not specifically illustrated, the positive electrode terminal 6P, the negative electrode terminal 6N, the three output terminal 8U, 8V, 8W, and the plurality of control terminals 9 as the external connection terminals are each electrically connected to the semiconductor chips 20A, 20B through, for example, the bonding wire 25 illustrated in FIG. 2 and FIG. 3 as a connection member. As the connection member, a plate lead may be used in place of the bonding wire 25.

### <Lid Member>

As illustrated in FIG. 1 and FIG. 2, the lid member 40 includes a plate having a principal surface and a back surface positioned opposite to each other in the thickness direction (Z direction) of the lid member 40. The outer peripheral shape of the lid member 40 in plan view is the same as the outer peripheral shape of the step 5c of the frame 5. In the first embodiment, into the step 5c of the frame 5, the lid member 40 is fitted, and the lid member 40 is fixed to the step 5c of the frame 5 by the fitting force between the frame 5 and the lid member 40. The fitting force is generated by the elastic deformation of at least one of the frame 5 and the lid member 40. The lid member 40 include the same material as the frame 5, for example.

### <Sealing Resin>

As illustrated in FIG. 2, the sealing resin 30 is filled in the recess 3 of the case member and is spaced from the back surface of the lid member 40. The sealing resin 30 covers and seals the insulating circuit board 10, the semiconductor chips 20A and 20B, the bonding wire 25, and the like placed in the recess 3 of the case member 2. In other words, the sealing resin 30 is filled in the recess 3 of the case member 2 to a height sufficient to seal the insulating circuit board 10, the semiconductor chips 20A and 20B, and the bonding wire 25.

The sealing resin 30 mainly include, for example, silicone gel. The silicone gel contains, as an oily component, a liquid low-molecular siloxane. The liquid low-molecular siloxane is contained at 20% or more and 30% or less. The liquid low-molecular siloxane intertwines into a chain structure and is filled in the gaps of polymeric siloxane. The liquid low-molecular siloxane functions as a cushioning material against thermal stress due to temperature changes. Hence, the liquid low-molecular siloxane maintains the insulation function against temperature changes of the sealing resin 30.

### <Inner Lid Member>

Not specifically illustrated, the inner lid member 51 illustrated in FIG. 2 includes a plate. As illustrated in FIG. 2, the inner lid member 51 is provided between the sealing resin 30 and the lid member 40 in the recess 3 of the case member 2 (inside the frame 5). The inner lid member 51 is supported by the lid member 40 through elastic bodies 55.

Not specifically illustrated, the inner lid member 51 has substantially the same planar shape as the planar shape of the opening of the recess 3 of the case member 2 (the principal surface of the frame 5) and has planar dimensions slightly smaller than the planar dimensions of the recess 3. The inner lid member 51 is slidable in the recess 3 in the thickness direction (Z direction) of the case member 2.

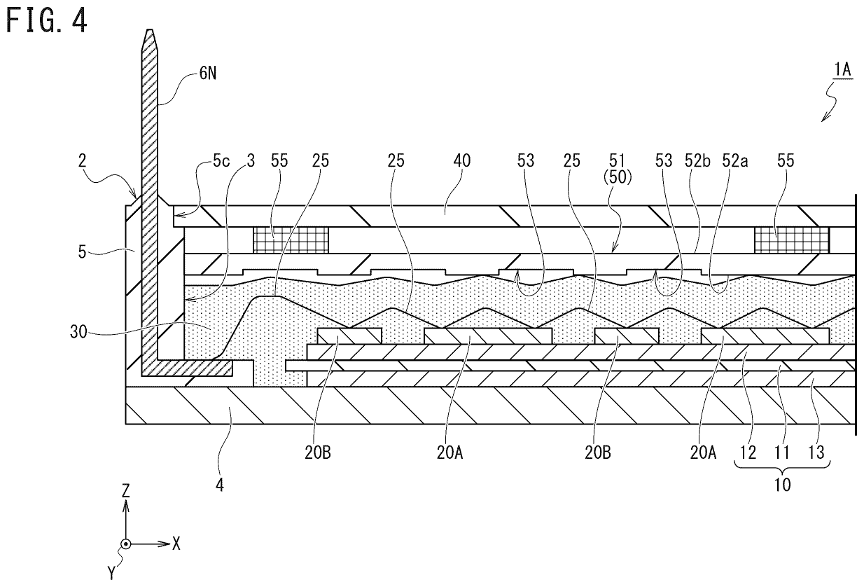

The semiconductor chips 20A, 20B and the bonding wire 25 illustrated in FIG. 3 have large current densities and generate a large amount of heat. Hence, the sealing resin 30 thermally expands in a region where a large amount of heat is generated, and partially swells as illustrated in FIG. 4. When a swelling portion of the sealing resin 30 comes into contact with the inner lid member 51 and generates a push-up force that pushes the inner lid member 51 upward, the elastic body 55 elastically deforms due to the push-up force exerted by the sealing resin 30 on the inner lid member 51. The inner lid member 51 is then moved upward by the elastic deformation of the elastic body 55 while sliding on the inner wall surface of the recess 3 of the case member 2 (the inside wall surface of the frame). In other words, the inner lid member 51 is supported by the lid member 40 through the elastic body 55 that elastically deforms due to the push-up force exerted on the inner lid member 51 by thermal expansion of the sealing resin 30. Examples of the elastic body 55 include, but are not necessarily limited to, a sponge that is a porous member having internal pores.

As illustrated in FIG. 3, the inner lid member 51 has a first surface 52a and a second surface 52b positioned opposite to each other in the thickness direction (Z direction) of the inner lid member 51. As illustrated in FIG. 2 and FIG. 3, the inner lid member 51 has, on the first surface 52a adjacent to the sealing resin 30, recesses 53 recessed in a direction away from the sealing resin 30. The recesses 53 are recessed from the first surface 52a toward the second surface 52b where the first surface 52a of the inner lid member 51 is the reference surface.

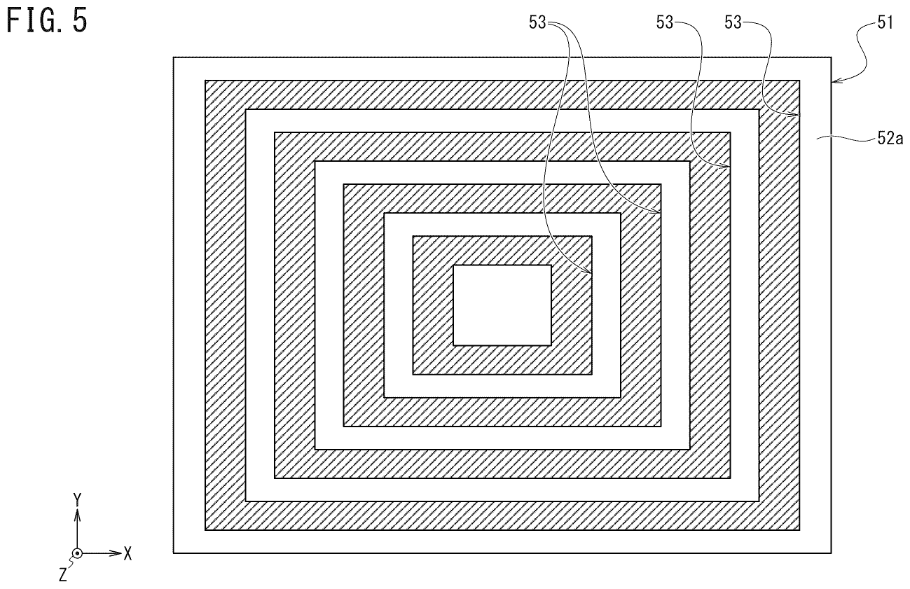

As illustrated in FIG. 3, the inner lid member 51 has a plurality of the recesses 53. As illustrated in FIG. 5, the plurality of recesses 53 are arranged in a concentric ring pattern while spaced from each other, but the arrangement is not limited to this pattern. The plurality of recesses 53 are provided apart from the outer peripheral edge of the inner lid member 51 in plan view and are provided inside the outer peripheral edge of the inner lid member 51. The inner lid member 51 having such a structure can store, in the recesses 53, an oily component seeping from inside the sealing resin 30 to the resin surface and can absorb the oily component.

If an inner lid member 51 were in contact with the resin surface of a sealing resin 30 from the initial state, an oily component would readily seep from inside the sealing resin 30 to the interface between the sealing resin 30 and the inner lid member 51. Hence, as illustrated in FIG. 3, the inner lid member is preferably separated from the resin surface to such an extent that a thermally expanded sealing resin 30 comes into contact with the inner lid member 51. Specifically, the clearance t₁ between the resin surface of the sealing resin 30 and the first surface 52a of the inner lid member 51 is preferably 0.5 mm or more and 2.0 mm or less.

<other Structure>

As illustrated in FIG. 2, the frame 5 has a protrusion 5d protruding inward from the frame 5 (into the recess 3). On the protrusion 5d, a semiconductor chip 23 is provided through a wiring board 22. The semiconductor chip 23 includes a control circuit. The amount of heat generated in the semiconductor chip 23 by operating the control circuit is smaller than the amount of heat generated in the semiconductor chips 20A and 20B including power devices. In other words, the semiconductor chips 20A and 20B including power devices each generate a larger amount of heat than the semiconductor chip 23 including a control circuit.

As illustrated in FIG. 2, the semiconductor chip 23 and the wiring board 22 are each covered with the sealing resin 30 as with the semiconductor chips 20A, 20B and the insulating circuit 10. The semiconductor chip 23 and the wiring board 22 are each superimposed on the inner lid member 51 in plan view as with the semiconductor chips 20A, 20B and the insulating circuit 10.

### <<Main Effect of First Embodiment>>

The main effect of the first embodiment will next be described.

The semiconductor device 1A according to the first embodiment includes, for example, a sealing resin 30 of silicone gel. When such a sealing resin 30 is used, an oily component seeps from inside the sealing resin 30 to the resin surface over time. In a conventional semiconductor device, which will be described using signs in FIG. 3 for the first embodiment, the oily component seeping to the resin surface of the sealing resin 30 flows on the inner wall surface of the frame 5 and leaks through the interface between the step of the frame 5 and the lid member 40 to the exterior.

In contrast, in the first embodiment, an inner lid member is provided as the oily component absorber 50 that is placed between the sealing resin 30 and the lid member and is to absorb an oily component seeping from inside the sealing resin to the resin surface. The inner lid member 51 has, on a first surface 52a adjacent to the sealing resin 30, recesses 53 recessed in a direction away from the sealing resin 30. The inner lid member 51 having such a structure can store, in the recesses 53, an oily component seeping from inside the sealing resin 30 to the resin surface and can absorb the oily component. Accordingly, the semiconductor device 1A according to the first embodiment can suppress external leakage of an oil component seeping from inside the sealing resin 30 to the resin surface, to outside the semiconductor device 1A.

In the above first embodiment, the device in which the lid member 40 is fixed to the step 5c of the frame 5 by the fitting force between the frame 5 and the lid member 40 has been described, but the outer peripheral edge portion of the lid member 40 may be adhesively fixed to the step 5c of the frame 5 through an adhesive. In the adhesive fixing with an adhesive, if the whole outer peripheral edge portion of a lid member 40 is adhesively fixed to a step of a frame 5, the following disadvantages may be caused: the bonding wire 25 or the semiconductor chips 20A, 20B having large current densities generate heat; the sealing resin 30 thermally expands; gas components sealed in the semiconductor device expand; the pressure in the case member 2 increases; and the lid is exploded and removed. It is therefore necessary to provide a region where the outer peripheral edge portion of the lid member 51 is not bonded to ensure a passage for gas to escape. In other words, even if the outer peripheral edge portion of the lid member 40 is adhesively fixed to the step 5c of the frame 5, a passage is needed. Through the passage, an oily component of the sealing resin 30 leaks outside the semiconductor device. Hence, even when the outer peripheral edge portion of the lid member 40 is adhesively fixed to the step 5c of the frame 5, providing the inner lid member 51 of the present technology enables the suppression of external leakage of an oil component seeping from inside the sealing resin 30 to the resin surface, to outside the semiconductor device 1A.

As illustrated in FIG. 1, the frame 5 has a smaller wall thickness in portions 5f with installation holes 5e than in the other portion. In the portion 5f, an adhesive would easily overflow into the installation hole 5e, and the dimensions of the installation hole might deviate. Hence, no adhesive is provided in the portion. Even in such a case, providing the inner lid member 51 of the present technology enables the suppression of external leakage of an oil component seeping from inside the sealing resin 30 to the resin surface, to outside the semiconductor device.

In the above first embodiment, the semiconductor chip 23 and the wiring board 22 are superimposed on the inner lid member 51 in plan view as with the semiconductor chips 20A, 20B and the insulating circuit 10, but the amount of heat generated in the semiconductor chip 23 is smaller than the amount of heat generated in the semiconductor chips 20A, 20B, and thus the inner lid member is not necessarily provided in a region superimposed on the semiconductor chip 23 in plan view. In other words, the inner lid member 51 may be provided selectively in a region superimposed on components generating a large amount of heat among the components sealed with the sealing resin 30.

### <<Alternative Embodiment of First Embodiment>>

In the above first embodiment, the device in which the flat pattern of the recesses 53 provided on the first surface 52a of the inner lid member 51 is a concentric ring pattern where a plurality of the recesses 53 are spaced from each other has been described, but the recesses 53 of the present technology are not limited to the first embodiment.

### <Alternative Embodiment 1-1>

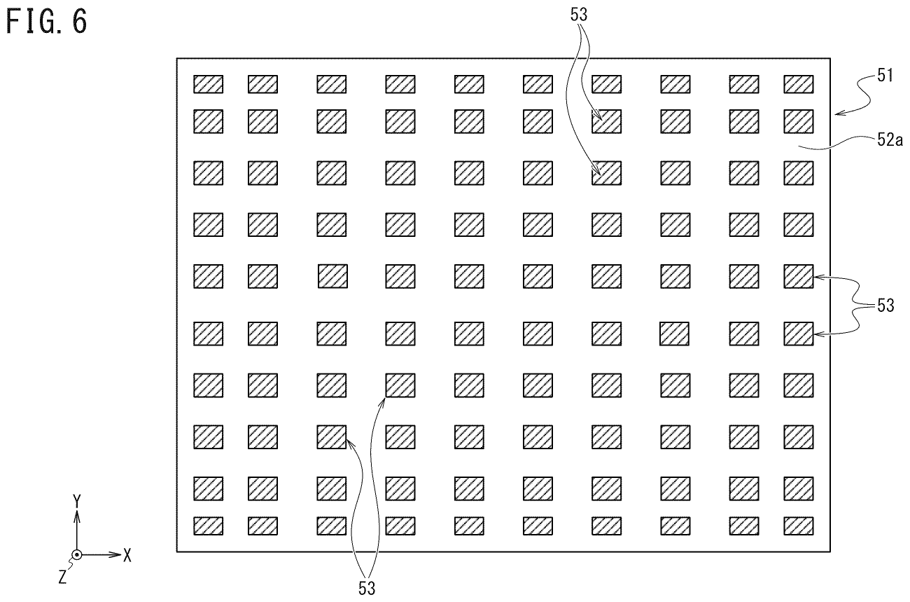

FIG. 6 is a plan view illustrating a flat pattern of recesses of an inner lid member in an alternative embodiment 1-1 according to the first embodiment of the present technology.

As illustrated in FIG. 6, in the alternative embodiment 1-1, a plurality of recesses 53 are provided in a dot pattern. In the alternative embodiment 1-1, the plurality of recesses 53 are provided apart from the outer peripheral edge of an inner lid member 51 in plan view and are provided inside the outer peripheral edge of the inner lid member 51, as with the above.

In the alternative embodiment 1-1, substantially the same effect as in the first embodiment is achieved.

### <Alternative Embodiment 1-2>

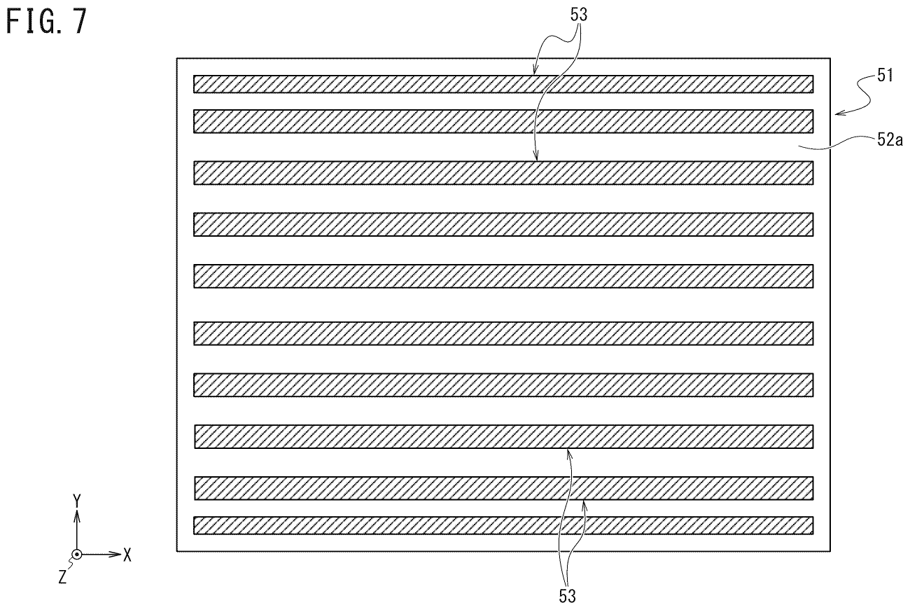

FIG. 7 is a plan view illustrating a flat pattern of recesses of an inner lid member in an alternative embodiment 1-2 according to the first embodiment of the present technology.

As illustrated in FIG. 7, in the alternative embodiment 1-2, a plurality of recesses 53 extending in the X direction are arranged at certain intervals in the Y direction. In the alternative embodiment 1-2, the plurality of recesses 53 are provided apart from the outer peripheral edge of an inner lid member 51 in plan view and are provided inside the outer peripheral edge of the inner lid member 51, as with the above.

In the alternative embodiment 1-2, substantially the same effect as in the first embodiment is achieved.

### <Alternative Embodiment 1-3>

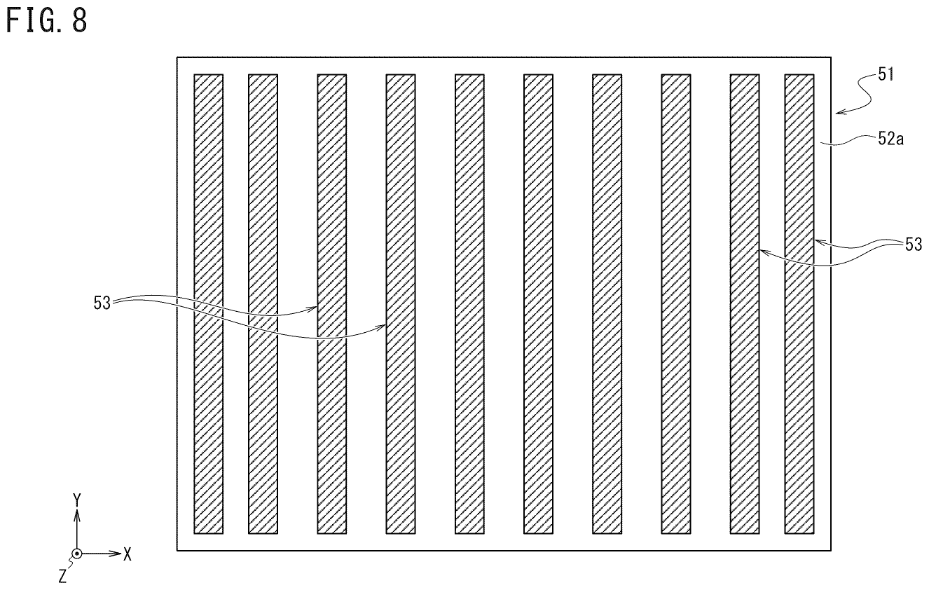

FIG. 8 is a plan view illustrating a flat pattern of recesses of an inner lid member in an alternative embodiment 1-3 according to the first embodiment of the present technology.

As illustrated in FIG. 8, in the alternative embodiment 1-3, a plurality of recesses 53 extending in the Y direction are arranged at certain intervals in the X direction. In the alternative embodiment 1-3, the plurality of recesses 53 are provided apart from the outer peripheral edge of an inner lid member 51 in plan view and are provided inside the outer peripheral edge of the inner lid member 51, as with the above.

In the alternative embodiment 1-3, substantially the same effect as in the first embodiment is achieved.

### <Alternative Embodiment 1-4>

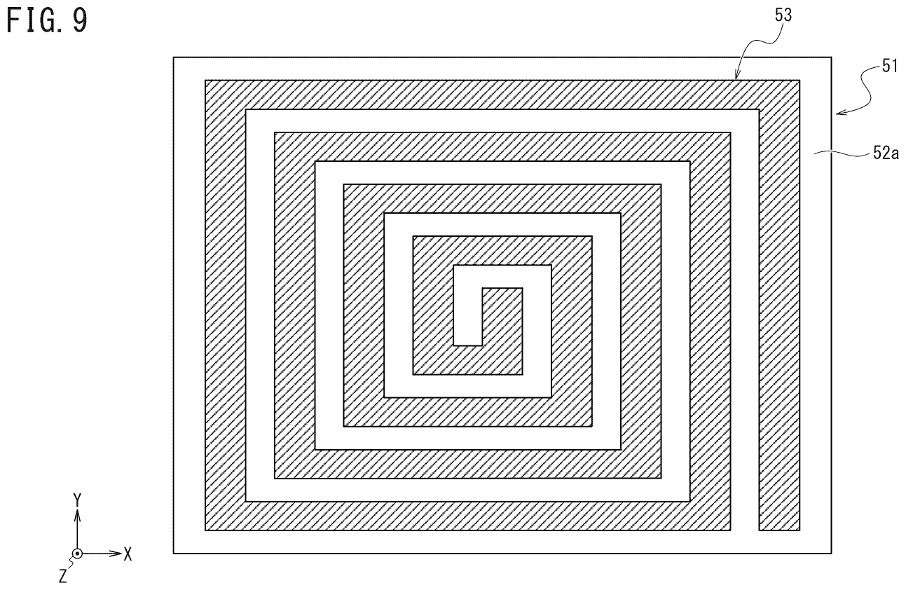

FIG. 9 is a plan view illustrating a flat pattern of a recess of an inner lid member in an alternative embodiment 1-4 according to the first embodiment of the present technology.

As illustrated in FIG. 9, in the alternative embodiment 1-4, a recess 53 continuously extends in a flat spiral pattern. In the alternative embodiment 1-4, the recess 53 is provided apart from the outer peripheral edge of an inner lid member 51 in plan view and is provided inside the outer peripheral edge of the inner lid member 51, as with the above.

In the alternative embodiment 1-4, substantially the same effect as in the first embodiment is achieved.

The spiral recess 53 may be separated into several segments.

### Second Embodiment

In the second embodiment, a device in which a porous insulating member is used as the oil component absorber will be described.

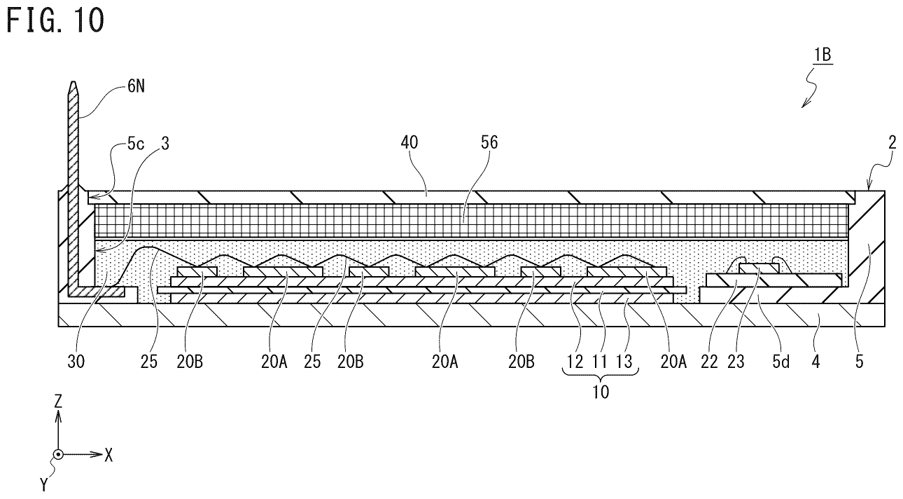

FIG. 10 is a longitudinal sectional view schematically illustrating the inner structure of a semiconductor device according to the second embodiment of the present technology.

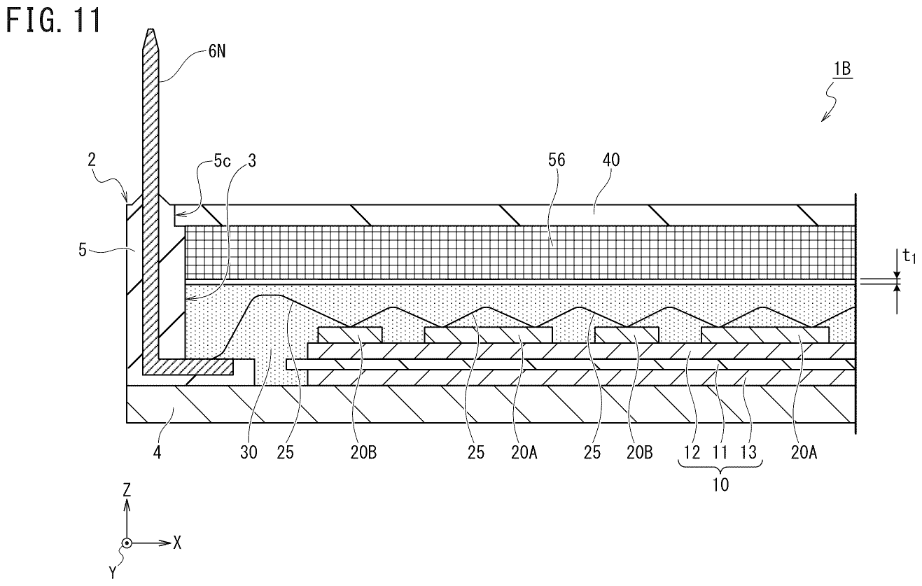

FIG. 11 is a longitudinal sectional view of an enlarged main portion in FIG. 10.

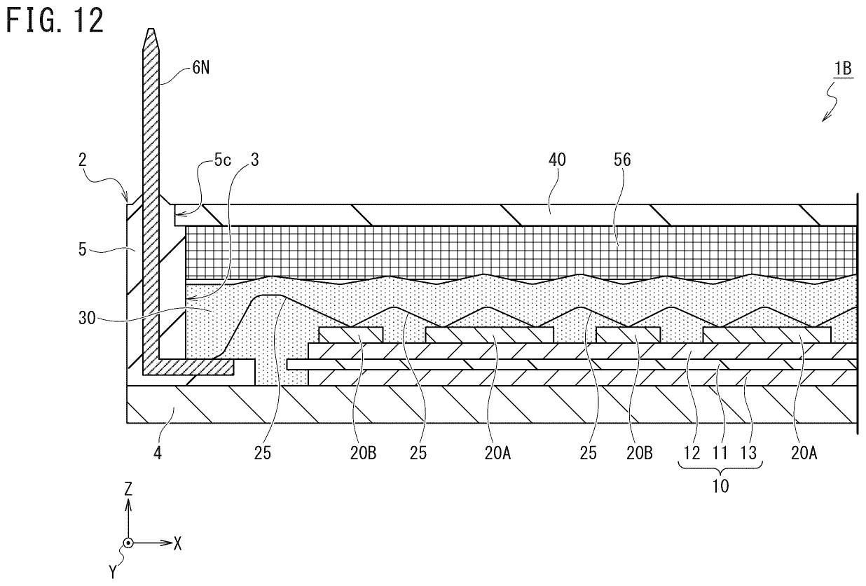

FIG. 12 is a longitudinal sectional view of a main portion schematically illustrating an example state in which a thermally expanded sealing resin is in contact with a porous insulating member in the second embodiment of the present technology.

A semiconductor device 1B according to the second embodiment of the present technology basically has substantially the same structure as the semiconductor device 1A according to the first embodiment, but differs in the following structure.

In other words, as illustrated in FIG. 10 and FIG. 11, the semiconductor device 1B according to the second embodiment of the present technology includes, as the oily component absorber 50 placed between the sealing resin 30 and the lid member 40 to absorb an oily component seeping from the sealing resin 30, a plate-shaped porous insulating member 56 having internal pores, in place of the plate-shaped inner lid member 51 of the first embodiment illustrated in FIG. 2.

Not specifically illustrated, the porous insulating member 56 includes a plate. As illustrated in FIG. 10 and FIG. 11, the porous insulating member 56 is provided between the sealing resin 30 and the lid member 40 in the recess 3 of the case member 2 (inside the frame 5). The porous insulating member 56 is directly supported by the lid member 40.

Not specifically illustrated, the porous insulating member 56 has substantially the same planar shape as the planar shape of the opening of the recess 3 of the case member 2 (the principal surface of the frame 5) and has substantially the same planar dimensions as the planar dimensions of the recess 3 unlike the inner lid member 51 in the first embodiment.

The semiconductor chips 20A, 20B and the bonding wire 25 illustrated in FIG. 11 have large current densities and generate a large amount of heat. Hence, the sealing resin 30 thermally expands in a region where a large amount of heat is generated, and partially swells as illustrated in FIG. 12. When a swelling portion of the sealing resin 30 comes into contact with the inner lid member 51 and generates a push-up force that pushes the porous insulating member 56 upward, the porous insulating member 56 elastically deforms due to the push-up force exerted by the sealing resin 30 on the porous insulating member 56. In other words, the porous insulating member 56 is an elastic body that elastically deforms due to a push-up force exerted on the porous insulating member by thermal expansion of the sealing resin 30. Examples of the porous insulating member 56 include, but are not necessarily limited to, a sponge.

The porous insulating member 56 having such a structure can absorb an oily component seeping from inside the sealing resin 30 to the resin surface.

As with the above inner lid member 51, if a porous insulating member 56 were in contact with the resin surface of a sealing resin 30 from the initial state, an oily component would readily seep from inside the sealing resin 30 to the interface between the sealing resin 30 and the porous insulating member 56. Hence, as illustrated in FIG. 8, the porous insulating member is preferably separated from the resin surface to such an extent that a thermally expanded sealing resin 30 comes into contact with the porous insulating member 56. Specifically, the clearance t₁ between the resin surface of the sealing resin 30 and the porous insulating member 56 is preferably 0.5 mm or more and 2.0 mm or less.

In the porous insulating member 56 in the second embodiment, an oily component seeping from inside the sealing resin 30 to the resin surface can be absorbed by the porous insulating member 56, and this can suppress external leakage of an oil component seeping from inside the sealing resin 30 to the resin surface, to outside the semiconductor device 1B, as with the above.

The porous insulating member 56 in the second embodiment may be provided selectively in a region superimposed on components generating a large amount of heat among the components sealed with the sealing resin 30, as with the above.

### Third Embodiment

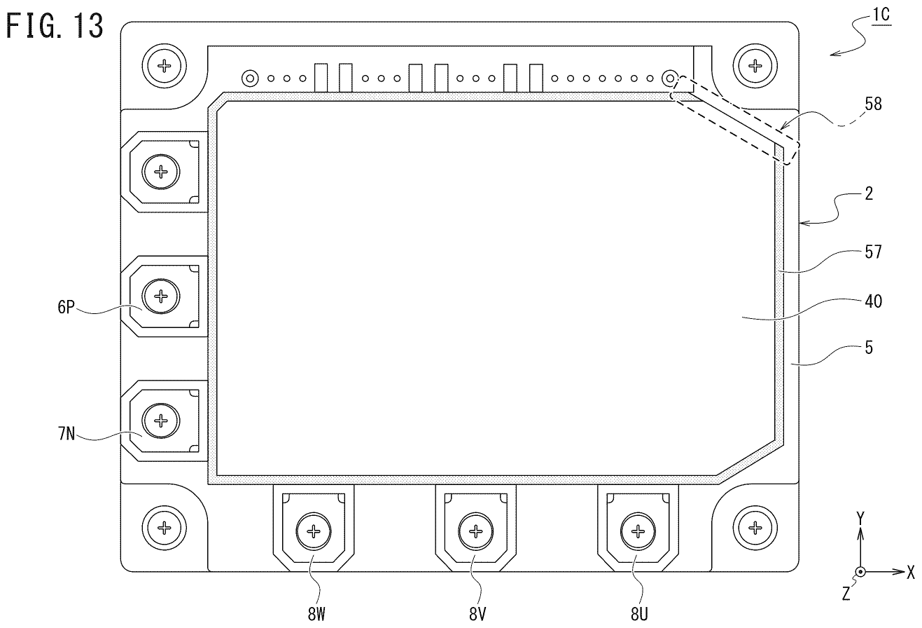

FIG. 13 is a plan view schematically illustrating the external structure of a semiconductor device according to a third embodiment of the present technology.

A semiconductor device 1C according to the third embodiment of the present technology basically has substantially the same structure as the semiconductor device 1A according to the first embodiment, but differs in the following structure.

In other words, as illustrated in FIG. 13, in the semiconductor device 1C according to the third embodiment, a frame 5 and a lid member 40 are adhesively fixed by applying an adhesive 57 with a dispenser from outside to the boundary between the frame 5 and the lid member 40 in plan view. In the semiconductor device 1C, it is also necessary to provide a region 58 not bonded with the adhesive 57 to ensure a passage connecting the recess 3 to the outside. Even in the semiconductor device 1C in which the frame 5 and the lid member 40 are adhesively fixed by applying the adhesive 57 with a dispenser from outside to the boundary between the frame 5 and the lid member 40 in plan view, providing the inner lid member 51 of the present technology enables the suppression of external leakage of an oil component seeping from inside the sealing resin 30 to the resin surface, to outside the semiconductor device 1C.

### Fourth Embodiment

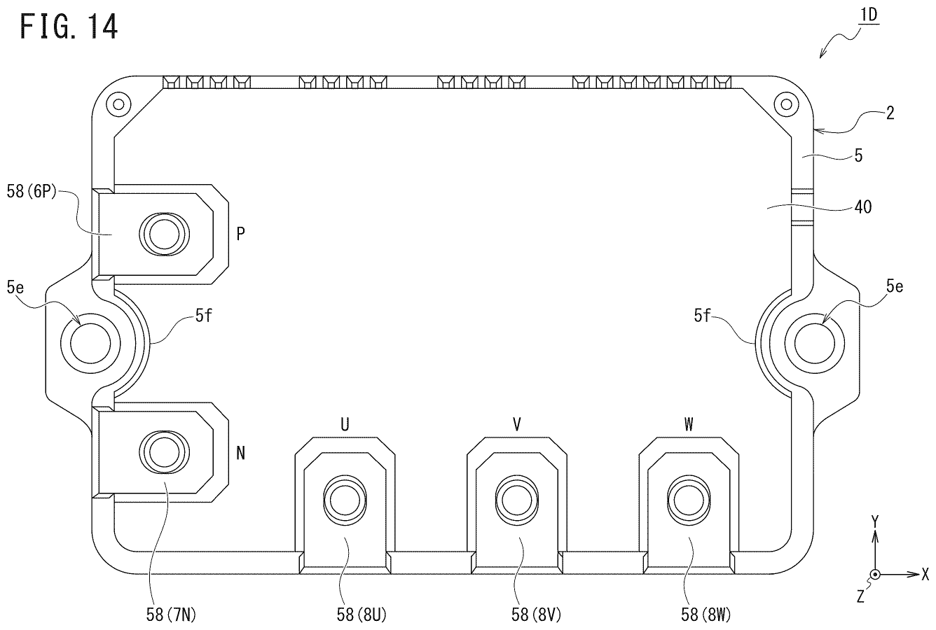

FIG. 14 is a plan view schematically illustrating the external structure of a semiconductor device according to a fourth embodiment of the present technology.

A semiconductor device 1D according to the fourth embodiment of the present technology basically has substantially the same structure as the semiconductor device 1A according to the first embodiment, but differs in the following structure.

In other words, as illustrated in FIG. 14, in the semiconductor device 1D according to the fourth embodiment, one ends of external connection terminals 58 (6P, 6N, 8U, 8V, 8W) are each bent inward the frame 5. In the structure, the one ends of the external connection terminals 58 cross the boundary between a frame 5 and a lid member 40 in plan view, and thus, to a boundary under the external connection terminals 58 in plan view, of the boundary between the frame 5 and the lid member 40, no adhesive is applied from outside. Hence, under the external connection terminals 58, passages are formed to connect the recess 3 of the case member to the outside. Even in the semiconductor device 1D in which one ends of the external terminals 58 are each bent inward, providing the inner lid member 51 of the present technology enables the suppression of external leakage of an oil component seeping from inside the sealing resin 30 to the resin surface, to outside the semiconductor device 1D.

The present technology has been specifically described on the basis of the above embodiments and the alternative embodiments, but the present technology (the technology according to the disclosure) is not limited to the embodiments and the alternative embodiments, and it is understood that various modifications may be made without departing from the scope.

### REFERENCE SIGNS LIST

1: semiconductor device
2: case member
3: recess
4: radiator plate
5: frame
5c: step
5d: protrusion
5e: installation hole
5f: portion
6P: positive electrode terminal
6N: negative electrode terminal
8U, 8V, 8W: output terminal
9: auxiliary terminal
10: insulating circuit board
11: insulating plate
12: circuit pattern
13: metal plate
20A, 20B: semiconductor chip
22: wiring board
23: semiconductor chip
30: sealing resin
40: lid member
50: oily component absorber
51: inner lid member
52a: first surface
52b: second surface
53: recess
55: elastic body
56: porous insulating member
57: adhesive
58: external connection terminal

1. A semiconductor device comprising:
a case member having a recess;
a semiconductor chip provided in the recess of the case member;
a sealing resin containing an oily component and provided in the recess of the case member to cover the semiconductor chip;
a lid member fixed to the case member to close an opening of the recess of the case member; and
an oily component absorber placed between the sealing resin and the lid member to absorb the oily component seeping from the sealing resin.

2. The semiconductor device according to claim 1, wherein the oily component absorber is separated from the sealing resin.

3. The semiconductor device according to claim 2, wherein a clearance between the oily component absorber and the sealing resin is 0.5 mm or more and 2.0 mm or less.

4. The semiconductor device according to claim 1, wherein the oily component absorber is a plate-shaped inner lid member having a recess on a surface adjacent to the sealing resin, and the recess is recessed in a direction away from the sealing resin.

5. The semiconductor device according to claim 4, wherein the recess of the inner lid member is located apart from an outer peripheral edge of the inner lid member in plan view.

6. The semiconductor device according to claim 4, wherein the inner lid member is supported by the lid member through an elastic body, and the elastic body elastically deforms due to a push-up force exerted on the inner lid member by thermal expansion of the sealing resin.

7. The semiconductor device according to claim 1, wherein the oily component absorber is a plate-shaped porous insulating member having internal pores.

8. The semiconductor device according to claim 7, wherein the porous insulating member is an elastic body, and the elastic body elastically deforms due to a push-up force exerted on the porous insulating member by thermal expansion of the sealing resin.

9. The semiconductor device according to claim 1, wherein
the case member includes a radiator plate and a frame, the frame is fixed to the radiator plate and surrounds a periphery of the semiconductor chip, and
the frame has an external terminal extending through the frame.

10. The semiconductor device according to claim 9, wherein the external terminal is electrically connected through a connection member to the semiconductor chip.

11. The semiconductor device according to claim 1, further comprising an insulating circuit board provided in the recess of the case member, wherein on the insulating circuit board, the semiconductor chip is installed.

12. The semiconductor device according to claim 1, wherein the sealing resin is a silicone gel containing, as the oily component, a liquid low-molecular siloxane.
